(19) United States
(12) Patent Application Publication
(10) Pub. No.: US 2012/0018814 A1
(43) Pub. Date: Jan. 26, 2012

(54) SEMICONDUCTOR DEVICE AND METHOD OF MANUFACTURING THE SAME

(75) Inventor: Tetsu Morooka, Yokohama-shi (JP)

(73) Assignee: KABUSHIKI KAISHA TOSHIBA, Tokyo (JP)

(21) Appl. No.: 13/185,585

(22) Filed: Jul. 19, 2011

(30) Foreign Application Priority Data
Jul. 20, 2010 (JP) 2010-163350

(51) Int. Cl. H01L 21/8234; H01L 27/088

(52) U.S. Cl. 257/392; 438/275; 257/E21.625; 257/E27.06

(57) ABSTRACT

According to one embodiment, a method of manufacturing a semiconductor device is disclosed as follows. A first oxide film in a first region and a second oxide film in a second region are formed on a semiconductor substrate. A high-k insulating film is formed on the first oxide film and the second oxide film. A film containing at least one of elements of Mg, La, Y, Dy, Sc, Al is formed on the high-k insulating film. After forming the film containing the element, thermal treatment is performed, so that the element in the film is diffused into the first oxide film and the second oxide film via the high-k insulating film. A metal gate electrode containing a metal material is formed on the high-k insulating film on the first oxide film and on the high-k insulating film on the second oxide film.

### CROSS-REFERENCE TO RELATED APPLICATIONS

This application is based upon and claims the benefit of priority from prior Japanese Patent Application No. 2010-163350, filed Jul. 20, 2010, the entire contents of which are incorporated herein by reference.

### FIELD

Embodiments described herein relate generally to a semiconductor device and a method of manufacturing the same.

### BACKGROUND

In general, a semiconductor integrated circuit includes an I/O portion having an input/output circuit formed therein and a core portion having a main circuit such as a logic circuit formed therein.

### BRIEF DESCRIPTION OF THE DRAWINGS

FIGS. 1A and 1B are cross-sectional views illustrating structures of MISFETs according to a first embodiment;

FIGS. 2A, 2B, 2C, 2D and 2E are cross-sectional views illustrating a method for manufacturing the MISFETs according to the first embodiment;

FIG. 3 is a figure illustrating interfacial layer film thickness dependency of a flat-band voltage of the MISFET according to the first embodiment with MgO;

FIG. 4 is a figure illustrating distribution of Mg in a gate insulating film and a gate electrode of the MISFET according to the first embodiment;

FIGS. 5A and 5B are figures illustrating a gate length dependency of a threshold voltage in the MISFET according to the first embodiment;

FIGS. 6A and 6B are cross-sectional views illustrating structures of MISFETs according to a second embodiment; and

FIGS. 7A, 7B, 7C, 7D and 7E are cross-sectional views illustrating a method for manufacturing the MISFETs according to the second embodiment.

### DETAILED DESCRIPTION

A semiconductor device having a MISFET according to embodiments will be hereinafter described with reference to the drawings. In this explanation, the same portions are denoted with the same reference numbers throughout the drawings.

In general, according to one embodiment, a method of manufacturing a semiconductor device, including: forming a first oxide film in a first region and a second oxide film in a second region on a semiconductor substrate; forming a high-k insulating film on the first oxide film and the second oxide film; forming a film containing at least one of elements of Mg, La, Y, Dy, Sc, Al, on the high-k insulating film; performing thermal treatment after forming the film containing the element, so that the element in the film is diffused into the first oxide film and the second oxide film via the high-k insulating film; and forming a metal gate electrode containing a metal material on the high-k insulating film on the first oxide film and on the high-k insulating film on the second oxide film.

### [1] First Embodiment

First, a MISFET according to the first embodiment will be explained.

[1-1] Structure of MISFET

A semiconductor device includes an I/O portion having an input/output circuit formed therein and a core portion having a main circuit such as a logic circuit formed therein. A MISFET in the I/O portion (hereinafter, I/O transistor) is required to have a higher Breakdown voltage than a MISFET in the core portion (hereinafter, core transistor). Therefore, the I/O transistor has a gate insulating film having a greater film thickness than the core transistor.

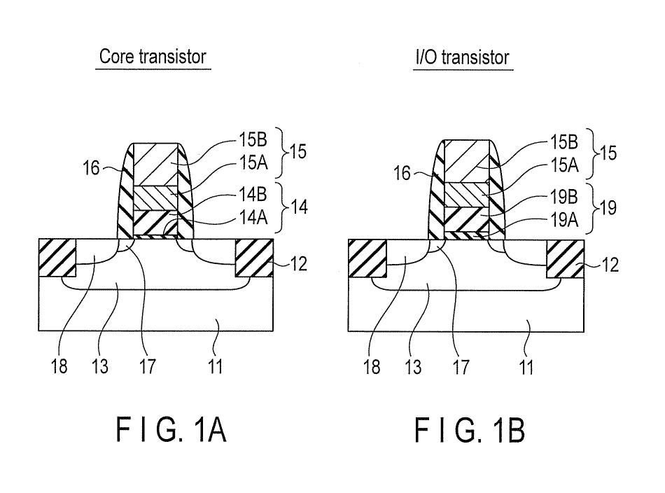

FIGS. 1A, 1B are cross-sectional views illustrating structures of the MISFETs according to the first embodiment. As shown in the figure, the core transistor as shown in FIG. 1A and the I/O transistor as shown in FIG. 1B are formed on a semiconductor substrate (for example, p-type silicon semiconductor substrate) 11.

The structure of the core transistor as shown in FIG. 1A will be hereinafter explained.

Device isolation regions 12 are formed in the semiconductor substrate 11. In a semiconductor substrate between the device isolation regions 12, a p-type well region 13 is formed as a device region. For example, the device isolation region 12 is made of silicon dioxide (SiO₂) film.

On the p-type well region 13, a gate insulating film 14 is formed. The gate insulating film 14 includes an interfacial layer 14A formed on the p-type well region 13 and a high-k insulating film 14B formed on the interfacial layer 14A. For example, the interfacial layer 14A is made of Silicon oxide (or SiON) film containing Mg, i.e., a compound of Silicon oxide (or SiON) and Mg. The high-k insulating film 14B is an insulating film made of a high dielectric constant (high-k) material, e.g., hafnium oxide (HfO₂) film containing Mg, i.e., a compound of Mg and hafnium oxide.

A gate electrode 15 is formed on the gate insulating film 14, i.e., the high-k insulating film 14B. The gate electrode 15 is made of a metal gate electrode containing metal materials. For example, the gate electrode 15 includes a titanium nitride (or tantalum nitride) film 15A formed on the high-k insulating film 14B and a polysilicon (or nickel suicide) film 15B formed on the titanium nitride film 15A.

Sidewall insulating films 16 are formed on sidewalls of the gate electrode 15 and the gate insulating film 14. For example, the sidewall insulating film 16 is made of silicon oxide film or silicon nitride film. Extension regions 17 are formed under the sidewall insulating film 16. Further, source and drain regions 18 are formed in the well region 13 sandwiched between the extension regions 17.

Subsequently, the structure of the I/O transistor as shown in FIG. 1B will be explained. The I/O transistor is formed on the same substrate 11 as the substrate formed with the core transistor.

Device isolation regions 12 are formed in the semiconductor substrate 11. In a semiconductor substrate between the device isolation regions 12, a p-type well region 13 is formed as a device region.

On the p-type well region 13, a gate insulating film 19 is formed. The gate insulating film 19 includes an interfacial layer 19A formed on the p-type well region 13 and a high-k insulating film 19B formed on the interfacial layer 19A. For example, the interfacial layer 19A is made of silicon oxide (or SiON) film containing Mg, i.e., a compound of Mg and silicon oxide (or SiON). The high-k insulating film 19B is an insulating film made of a high-k material, e.g., hafnium oxide film containing Mg, i.e., a compound of Mg and hafnium oxide.

In this case, the film thickness of the interfacial layer 19A is greater than the film thickness of the interfacial layer 14A. The amount of Mg contained in the interfacial layer 19A is more than the amount of Mg contained in the interfacial layer 14A.

A gate electrode 15 is formed on the gate insulating film 19, i.e., the high-k insulating film 19B. The gate electrode 15 is made of a metal gate electrode containing metal materials. For example, the gate electrode 15 includes a titanium nitride (or tantalum nitride) film 15A formed on the high-k insulating film 19B and a polysilicon (or nickel suicide) film 15B formed on the titanium nitride film 15A.

Sidewall insulating films 16 are formed on sidewalls of the gate electrode 15 and the gate insulating film 14. For example, the sidewall insulating film 16 is made of silicon oxide film or silicon nitride film. Extension regions 17 are formed under the sidewall insulating film 16. Further, source and drain regions 18 are formed in the well region 13 sandwiched between the extension regions 17.

[1-2] Method of Manufacturing MISFET

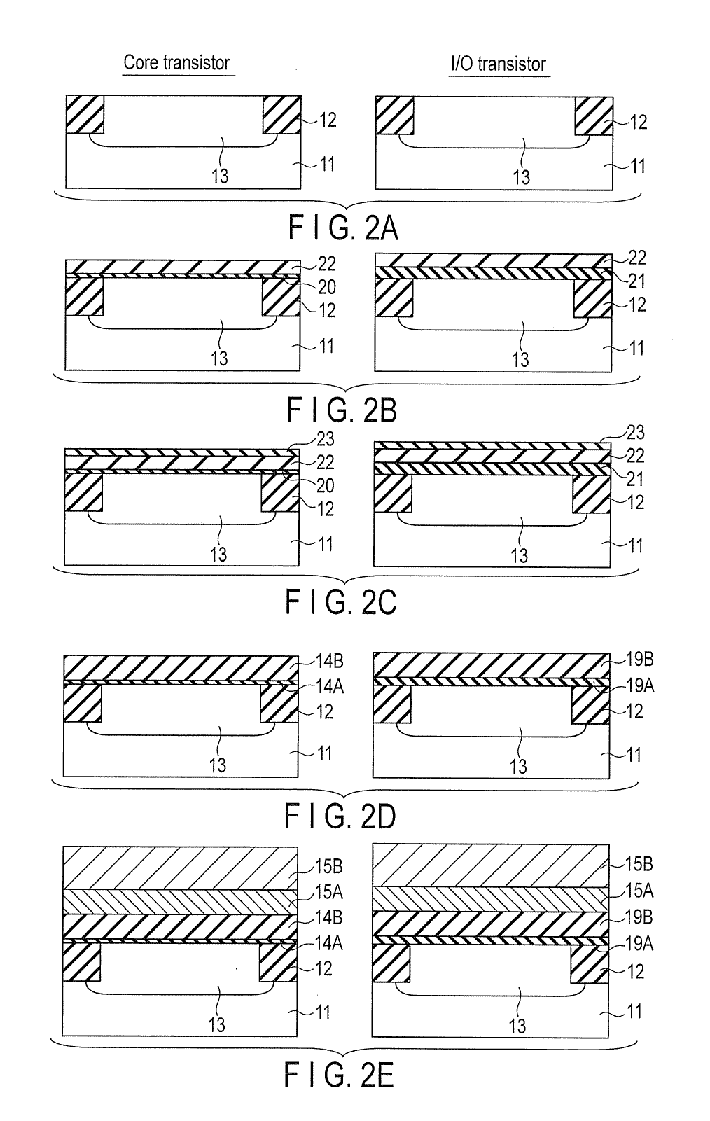

FIGS. 2A to 2E are cross-sectional views illustrating a method for manufacturing the MISFETs according to the first embodiment.

First, as shown in FIG. 2A, the device isolation regions 12 are formed in a core transistor formation region (hereinafter, core region) and an I/O transistor formation region (I/O region) of the semiconductor substrate 11. Then, a well region 13 is formed between the device isolation regions 12 by ion implantation in the semiconductor substrate 11. Further, ion implantation is performed on the core region and the I/O region under the same condition in the same step in order to adjust threshold voltages of transistors. In other words, the same dose amount of impurity is injected into the core region and the I/O region by the ion implantation using the same acceleration voltage.

Subsequently, as shown in FIG. 2B, a silicon oxide film 20 is formed by thermal oxidation method on the well region 13 and the device isolation region 12 of the core region. Likewise, a silicon oxide film 21 is formed by thermal oxidation method on the well region 13 and the device isolation region 12 of the I/O region. In this case, the silicon oxide film 21 formed in the I/O region has a greater film thickness than the silicon oxide film 20 formed in the core region.

Further, as shown in FIG. 2B, insulating films made of a high-k material, e.g., hafnium oxide films 22, are formed on the silicon oxide films 20, 21. At this time, the hafnium oxide films 22 are deposited onto the core region and the I/O region in the same step, and each of the hafnium oxide films 22 has the same film thickness.

Further, as shown in FIG. 2C, films including at least one of elements of Mg, La, Y, Dy, Sc, Al, e.g., MgO (or Mg) films 23, are formed on the hafnium oxide film 22. At this time, the MgO films 23 are deposited onto the core region and the I/O region in the same step, and each of the MgO films 23 has the same film thickness.

Thereafter, thermal treatment is applied to the structures as shown in FIG. 2C, so that Mg in the MgO (or Mg) films 23 is diffused into the hafnium oxide film 22 and the silicon oxide films 20, 21. At this time, the temperature of the thermal treatment is preferably 1000 to 1100° C. As a result, as shown in FIG. 2D, the interfacial layer 14A and the high-k insulating film 14B are formed in the core region, and the interfacial layer 19A and the high-k insulating film 19B are formed in the I/O region.

The interfacial layers 14A, 19A are made of silicon oxide film containing Mg, i.e., a compound of Mg and silicon oxide. The high-k insulating films 14B, 19B are made of hafnium oxide films containing Mg, i.e., a compound of Mg and hafnium oxide. In this case, the interfacial layer 19A has a greater film thickness than the interfacial layer 14A, and accordingly the amount of Mg included in the interfacial layer 19A is more than the amount of Mg included in the interfacial layer 14A.

Subsequently, as shown in FIG. 2E, a titanium nitride (or tantalum nitride) film 15A is formed on the high-k insulating films 14B, 19B, and for example, a polysilicon or metal silicide film (for example, nickel silicide film) 15B is formed on the titanium nitride films 15A.

Subsequently, as shown in FIGS. 1A and 1B, the polysilicon film 15B and titanium nitride film 15A are etched by, e.g., reactive ion etching (RIE), so that the gate electrodes 15 are formed. Further, the high-k insulating film 14B, the interfacial layer 14A, the high-k insulating film 19B, and the interfacial layer 19A are etched by, e.g., RIE, so that the gate insulating films 14, 19 are respectively formed.

Thereafter, as shown in FIGS. 1A and 1B, the extension regions 17 are formed in the well regions 13 at both sides of the gate electrodes 15 and the gate insulating films 14 and 19. Subsequently, the sidewall insulating films 16 are formed on the sidewalls of the gate electrode 15. Further, the source and drain regions 18 are formed in the well region 13 at both sides of the sidewall insulating films 16. According to the above steps, the core transistor and the I/O transistor are made on the same semiconductor substrate 11.

[1-3] Advantages and Effects

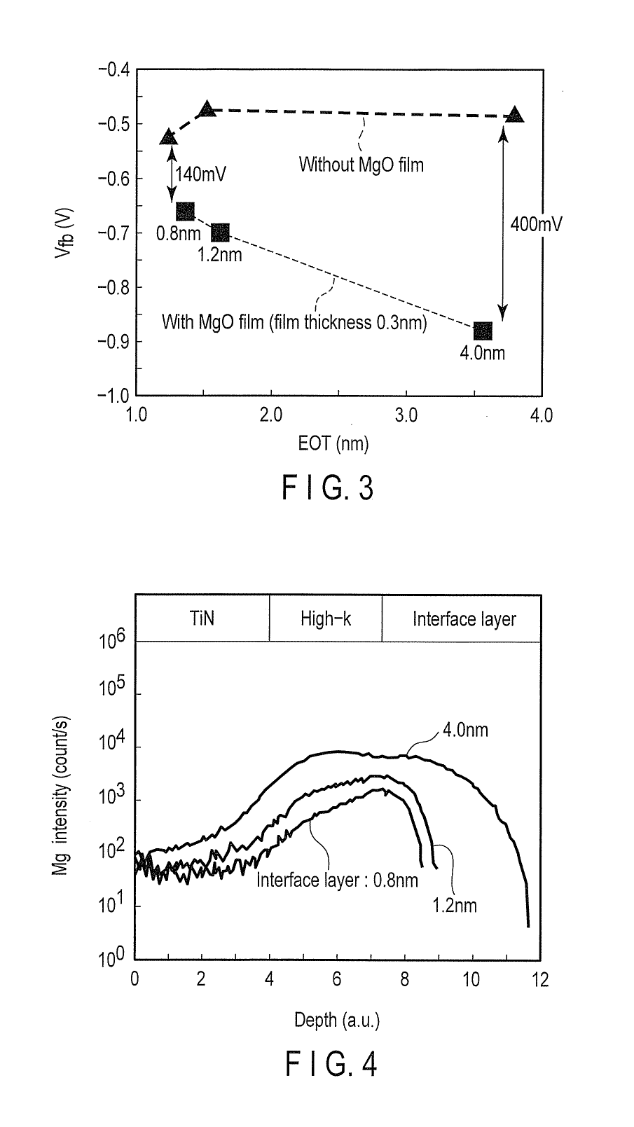

FIG. 3 illustrates flat-band voltage (V_{fb}) of MISFET with and without MgO depends on interfacial layer film thickness. The temperature of the thermal treatment that the MgO films 23 are diffused to the high-k insulating films 14B, 19B and the interfacial layers 14A, 19A is 1050° C. The flat-band voltage is one of factors that determine the threshold voltage (Vt) of MISFETs. When the flat-band voltage shifts in a negative direction, the threshold voltage also shifts in a negative direction. The Equivalent oxide thickness (EOT) is the thickness of gate insulating films 14, 19 converting into silicon oxide film thickness. In FIG. 3, 0.8 nm, 1.2 nm, and 4.0 nm are film thickness of the interfacial layer. When the MgO film is not deposited, the dependence of the flat-band voltage on interfacial layer film thickness is small. In contrast, when the MgO film is deposited, it is understood that a greater film thickness of the interfacial layer induces more negative shift of the flat-band voltage in spite of the thickness of MgO films are same.

FIG. 4 illustrates distribution of Mg in the gate insulating film (high-k insulating film and interfacial layer) and the gate electrode (titanium nitride) in the MISFET. Count/s in the vertical axis is the number of counts of Mg detected by a detector per unit time (in this case, one second). When the number of counts is larger, this means that there are more Mg atoms. In FIG. 4, 0.8 nm, 1.2 nm, and 4.0 nm are film thickness of the interfacial layer. It is understood that, when the film thickness of the interfacial layer is larger, the amount of Mg atoms is larger in the gate insulating film. Accordingly, the greater the film thickness of the interfacial layer is, the larger the amount of Mg atoms in the interfacial layer is, and the flat-band voltage is considered to shift in the negative direction.

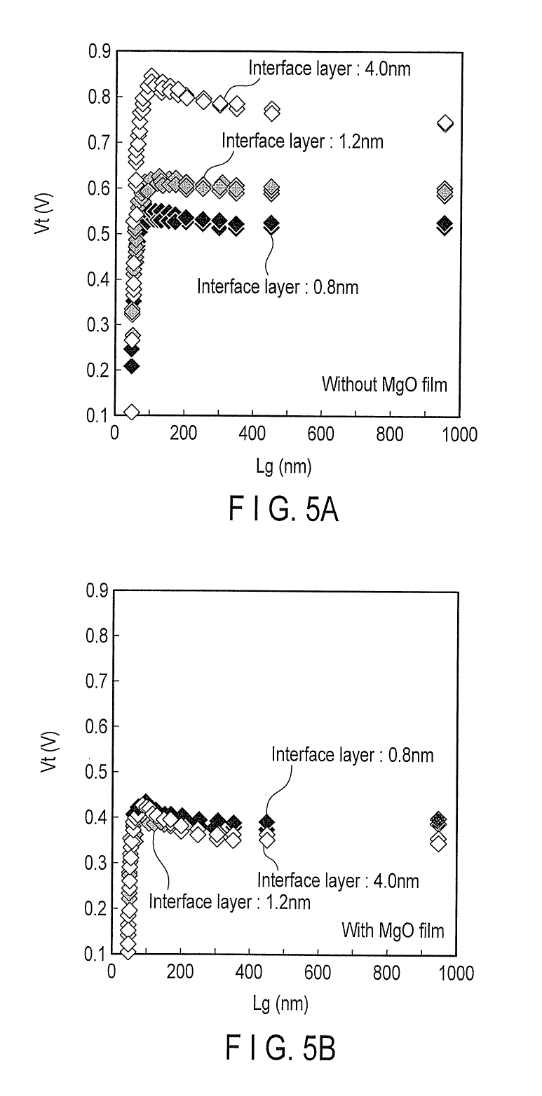

FIGS. 5A and 5B illustrate the dependence of the threshold voltage on gate length (Lg) in the MISFET. FIG. 5A shows a case where the MgO film is not deposited. FIG. 5B shows a case where the MgO film is deposited.

In FIG. 5, 0.8 nm, 1.2 nm, and 4.0 nm are film thickness of the interfacial layer. As shown in FIG. 5A, when the MgO film is not deposited, a greater film thickness of the interfacial layer results in a higher threshold voltage. On the other hand, as shown in FIG. 5B, when the MgO film is deposited, the threshold voltage is reduced. And a greater film thickness of the interfacial layer induces more negative shift of the threshold voltage. Therefore, in the case where the MgO film is deposited, even when the film thickness of the interfacial layer increases, the substantially the same threshold voltage can be obtained.

Therefore, even when the film thickness of the gate insulating film (interfacial layer) of the I/O transistor is greater than the film thickness of the gate insulating film (interfacial layer) of the core transistor, the interfacial layer of the I/O transistor contains more Mg atoms per unit area than the interfacial layer of the core transistor. Therefore, the threshold voltage of the I/O transistor is reduced to a level less than the threshold voltage of the core transistor. Further, substantially the same threshold voltage can be obtained without relying on the film thickness of MgO. Using this, the threshold voltages of the core transistor and the I/O transistor can be adjusted to substantially the same level by adjusting the film thicknesses of the interfacial layers of the core transistor and the I/O transistor in the first embodiment. In this case, the content of Mg atoms per unit area is represented by the number of Mg atoms included in unit area of the interfacial layer when the interfacial layer is seen from above.

It is not necessary to separately perform the ion implantation for both of the core transistor and the I/O transistor in order to adjust the threshold voltages. The ion implantation for both of the core transistor and the I/O transistor can be performed in the same step under the same condition. In other words, the well regions under the gate insulating films of the core transistor and the I/O transistor can be made to have the same concentration. Therefore, the steps for manufacturing can be simplified.

Moreover, the MgO film formed on the gate insulating film (interfacial layer) may be deposited in the same step with the same film thickness. Therefore, the steps for manufacturing can be simplified even in this respect.

As described above, according to the first embodiment, the semiconductor device and the method of manufacturing the same can be provided that can adjust the threshold voltages of both of the MISFET of the core portion and the MISFET of the I/O portion, which have different breakdown voltages. In other words, the semiconductor device and the method of manufacturing the same can be provided that can adjust the threshold voltages of MISFETs having different high-k gate insulating films having different film thicknesses.

### [2] Second Embodiment

In general, the MISFET in the core portion (core transistor) has a smaller channel size than the MISFET in the I/O portion (I/O transistor). Accordingly, in the MISFET in the core portion, the element such as La, Y, Mg, Dy, Sc, or Al is likely to diffuse from the high-k insulating film to a region outside of the channel region such as the device isolation region. On the other hand, in the I/O transistor in which the channel size is large and the interfacial layer is thick, the element such as La, Y, Mg, Dy, Sc, or Al hardly diffuses from the high-k insulating film to a region outside of the channel region such as the device isolation region. Using this, in an example of the second embodiment, the amount of element taken into the interfacial layer of the core transistor is reduced, and the amount of element taken into the interfacial layer of the I/O transistor is increased, whereby the threshold voltage is adjusted.

[2-1] Structure of MISFET

A semiconductor device includes an I/O portion having an input/output circuit formed therein and a core portion having a main circuit such as a logic circuit formed therein. A MISFET in the I/O portion (I/O transistor) is required to have a higher breakdown voltage than a MISFET in the core portion (core transistor). Therefore, the I/O transistor has a gate insulating film having a greater film thickness than the core transistor.

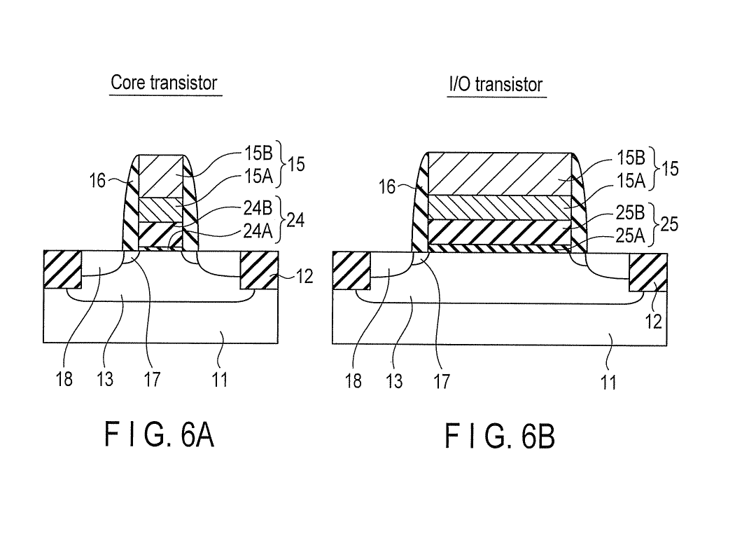

FIGS. 6A and 6B are cross-sectional views illustrating structures of MISFETs according to the second embodiment. As shown in the figure, the core transistor as shown in FIG. 6A and the I/O transistor as shown in FIG. 6B are formed on a semiconductor substrate 11.

The structure of the core transistor as shown in FIG. 6A will be hereinafter explained.

Device isolation regions 12 are formed in the semiconductor substrate 11. In a semiconductor substrate between the device isolation regions 12, a p-type well region 13 is formed as a device region. For example, the device isolation region 12 is made of silicon oxide (SiO₂) film.

On the p-type well region 13, a gate insulating film 24 is formed. The gate insulating film 24 includes an interfacial layer 24A formed on the p-type well region 13 and a high-k insulating film 24B formed on the interfacial layer 24A. The interfacial layer 24A is made of a silicon oxide (or SiON) film containing at least one of elements of, e.g., La, Y, Mg, Dy, Sc, Al (hereinafter referred to as additional elements), i.e., a compound of the additional element and silicon oxide (or SiON). The high-k insulating film 24B is an insulating film made of a high dielectric constant (high-k) material, e.g., hafnium oxide (HfO₂) film containing the additional element, i.e., a compound of the additional element and hafnium oxide.

A gate electrode 15 is formed on the gate insulating film 24, i.e., the high-k insulating film 24B. The gate electrode 15 is made of a metal gate electrode containing metal materials. For example, the gate electrode 15 includes a titanium nitride (or tantalum nitride) film 15A formed on the high-k insulating film 24B and a polysilicon (or nickel silicide) film 15B formed on the titanium nitride film 15A. Sidewall insulating films 16 are formed on sidewalls of the gate electrode 15 and the gate insulating film 24. Extension regions 17 are formed under the sidewall insulating film 16. Further, source and drain regions 18 are formed in the well region 13 sandwiched between the extension regions 17.

Subsequently, the structure of the I/O transistor as shown in FIG. 6B will be explained. The I/O transistor is formed on the same substrate 11 as the substrate formed with the core transistor.

Device isolation regions 12 are formed in the semiconductor substrate 11. In a semiconductor substrate between the device isolation regions 12, a p-type well region 13 is formed as a device region.

On the p-type well region 13, a gate insulating film 25 is formed. The gate insulating film 25 includes an interfacial layer 25A formed on the p-type well region 13 and a high-k insulating film 25B formed on the interfacial layer 25A. The interfacial layer 25A is made of a silicon oxide (or SiON) film containing at least one of elements of, e.g., La, Y, Mg, Dy, Sc, Al (additional elements), i.e., a compound of the additional element and silicon oxide (or SiON). The high-k insulating film 25B is an insulating film made of a high-k material, e.g., hafnium oxide film containing the additional element, i.e., a compound of the additional element and hafnium oxide.

In this case, the film thickness of the interfacial layer 25A is greater than the film thickness of the interfacial layer 24A. On the other hand, the amount of the additional element contained in the interfacial layer 25A is more than the amount of the additional element contained in the interfacial layer 24A. When seen from above the surface of the semiconductor substrate 11, the area of the interfacial layer 25A is larger than the area of the interfacial layer 24A.

A gate electrode 15 is formed on the gate insulating film 25, i.e., the high-k insulating film 25B. The gate electrode 15 is made of a metal gate electrode containing metal materials. For example, the gate electrode 15 includes a titanium nitride (or tantalum nitride) film 15A formed on the high-k insulating film 25B and a polysilicon (or nickel silicide) film 15B formed on the titanium nitride film 15A.

Sidewall insulating films 16 are formed on sidewalls of the gate electrode 15 and the gate insulating film 25. Extension regions 17 are formed under the sidewall insulating film 16. Further, source and drain regions 18 are formed in the well region 13 sandwiched between the extension regions 17. The structure other than the above is the same as the first embodiment.

[2-2] Method of Manufacturing MISFET

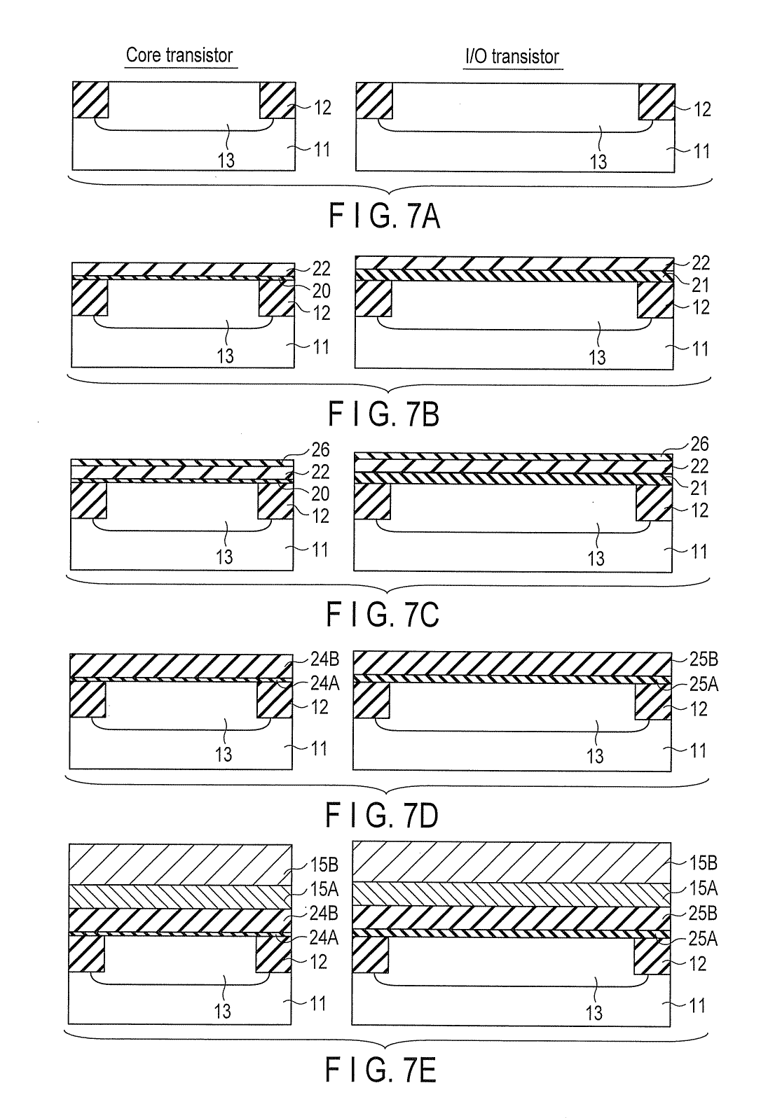

FIGS. 7A to 7E are cross-sectional views illustrating a method for manufacturing the MISFETs according to the second embodiment.

First, as shown in FIG. 7A, the device isolation regions 12 are formed in a core transistor formation region (core region) and an I/O transistor formation region (I/O region) of the semiconductor substrate 11. Then, a well region 13 is formed between the device isolation regions 12 by ion implantation in the semiconductor substrate 11. Further, ion implantation is performed on the core region and the I/O region under the same condition in the same step in order to adjust threshold voltages.

Subsequently, as shown in FIG. 7B, a silicon oxide film 20 is formed by thermal oxidation method on the well region 13 and the device isolation region 12 of the core region. Likewise, a silicon oxide film 21 is formed by thermal oxidation method on the well region 13 and the device isolation region 12 of the I/O region. In this case, the silicon oxide film 21 formed in the I/O region has a greater film thickness than the silicon oxide film 20 formed in the core region. When seen from above the surface of the semiconductor substrate 11, the area of the interfacial layer 21 is larger than the area of the interfacial layer 20.

Further, as shown in FIG. 7B, insulating films made of a high-k material, e.g., hafnium oxide films 22, are formed on the silicon oxide films 20, 21. At this time, the hafnium oxide films 22 are deposited onto the core region and the I/O region in the same step, and each of the hafnium oxide films 22 has the same film thickness.

Further, as shown in FIG. 7C, films (for example, an oxide film) 26 containing at least one of elements of, e.g., Mg, La, Y, Dy, Sc, Al (additional elements) are formed on the hafnium oxide films 22. The films 26 are deposited onto the core region and the I/O region in the same step, and each of the films 26 has the same film thickness.

Thereafter, thermal treatment is applied to the structures as shown in FIG. 7C, so that the additional element in the films 26 including the additional element are diffused into the hafnium oxide film 22 and the silicon oxide films 20, 21. At this time, the temperature of the thermal treatment is preferably 1000 to 1100° C. As a result, as shown in FIG. 7D, the interfacial layer 24A and the high-k insulating film 24B are formed in the core region, and the interfacial layer 25A and the high-k insulating film 25B are formed in the I/O region.

The interfacial layers 24A, 25A are made of silicon oxide films containing the additional element, i.e., a compound of the additional element and silicon oxide. The high-k insulating films 24B, 25B are made of hafnium oxide films containing the additional element, i.e., a compound of the additional element and hafnium oxide.

In this case, the device region of the I/O region is sufficiently larger than the device region of the core region, and the interfacial layer thereof is thick. Therefore, the additional element hardly diffuses from the interfacial layer (silicon oxide film) 25A and the high-k insulating film (hafnium oxide film) 25B containing the additional elements to a region outside of the device region such as the device isolation region 12. On the other hand, in the core region in which the device region is small and the interfacial layer is thin, the additional element is likely to diffuse from the interfacial layer (silicon oxide film) 24A and the high-k insulating film (hafnium oxide film) 24B containing the additional elements to a region outside of the device region such as the device isolation region 12.

Therefore, a larger amount of additional element remains in the I/O region than in the core region.

Subsequently, as shown in FIG. 7E, a titanium nitride (or tantalum nitride) film 15A is formed on the high-k insulating films 24B, 25B, and for example, a polysilicon (or nickel suicide) film 15B is formed on the titanium nitride films 15A.

As shown in FIGS. 6A and 6B, the polysilicon film 15B and titanium nitride film 15A are etched by, e.g., RIE, so that the gate electrodes 15 are formed. Further, the high-k insulating film 24B, the interfacial layer 24A, the high-k insulating film 25B, and the interfacial layer 25A are etched by, e.g., RIE, so that the gate insulating films 24, 25 are respectively formed.

Thereafter, as shown in FIGS. 6A and 6B, the extension regions 17 are formed in the well region 13 at both sides of the gate electrode 15. Subsequently, the sidewall insulating films 16 are formed on the sidewalls of the gate electrodes 15 and the gate insulating films 24 and 25. Further, the source and drain regions 18 are formed in the well region 13 at both sides of the sidewall insulating films 16. According to the above steps, the core transistor and the I/O transistor are made on the same semiconductor substrate 11. The manufacturing method other than the above is the same as the first embodiment.

[2-3] Advantages and Effects

In the second embodiment, even when the film thickness of the gate insulating film (interfacial layer) of the I/O transistor is greater than the film thickness of the gate insulating film (interfacial layer) of the core transistor, the interfacial layer of the I/O transistor has a larger amount of at least one of elements of, e.g., La, Y, Mg, Dy, Sc, Al (additional elements) than the interfacial layer of the core transistor per unit area. Therefore, the threshold voltage of the I/O transistor is reduced to a level less than the threshold voltage of the core transistor. In addition, as in the first embodiment, substantially the same threshold voltage can be obtained without relying on the film thickness of the films containing at least one on elements of e.g., Mg, La, Y, Dy, Sc, Al (additional elements). Using this, the threshold voltages of the core transistor and the I/O transistor can be adjusted to substantially the same level by adjusting the film thicknesses of the interfacial layers of the core transistor and the I/O transistor in the second embodiment.

It is not necessary to separately perform the ion implantation for both of the core transistor and the I/O transistor in order to adjust the threshold voltages. The ion implantation for both of the core transistor and the I/O transistor can be performed in the same step under the same condition. In other words, the well regions under the gate insulating films of the core transistor and the I/O transistor can be made to have the same concentration. Therefore, the steps for manufacturing can be simplified.

Moreover, the film containing the additional element formed on the gate insulating film (interfacial layer) may be deposited in the same step with the same film thickness. Therefore, the steps for manufacturing can be simplified even in this respect.

As described above, according to the second embodiment, the semiconductor device and the method of manufacturing the same can be provided that can adjust the threshold voltages of both of the MISFET of the core portion and the MISFET of the I/O portion, which have different breakdown voltages. In other words, the semiconductor device and the method of manufacturing the same can be provided that can adjust the threshold voltages of MISFETs having different high-k gate insulating films having different film thicknesses.

According to the present embodiment, the semiconductor device and the method of manufacturing the same can be provided that can adjust the threshold voltage of the metal-insulator semiconductor field-effect transistors (MISFETs) having high-k gate insulating film having different interfacial layer film thicknesses.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a first oxide film in a first region and a second oxide film in a second region on a semiconductor substrate;
forming a high-k insulating film on the first oxide film and the second oxide film;
forming a film containing at least one of elements of Mg, La, Y, Dy, Sc, Al, on the high-k insulating film;
performing thermal treatment after forming the film containing the element, so that the element in the film is diffused into the first oxide film and the second oxide film via the high-k insulating film; and
forming a metal gate electrode containing a metal material on the high-k insulating film on the first oxide film and on the high-k insulating film on the second oxide film.

2. The method of claim 1,
wherein when the first and second oxide films are formed, the first oxide film is formed to have a first film thickness, and the second oxide film is formed to have a second film thickness larger than the first film thickness.

3. The method of claim 1,
wherein after the element is diffused, the amount of the element contained in the first oxide film is a first amount per unit area, and the amount of the element contained in the second oxide film is a second amount larger than the first amount per unit area.

4. The method of claim 1,
wherein the area of the second oxide film is larger than the area of the first oxide film.

5. The method of claim 1, further comprising performing ion implantation into the first and second regions under a same condition before forming the first oxide film and the second oxide film.

6. The method of claim 1,
wherein when the high-k insulating film is formed, the high-k insulating film is formed to have a same film thickness on the first oxide film and on the second oxide film.

7. The method of claim 1,
wherein the high-k insulating film includes a hafnium oxide film.

8. The method of claim 1,
wherein when the film containing the element is formed, the film containing the element is formed to have a same film thickness above the first oxide film and above the second oxide film.

9. The method of claim 1,
wherein the film containing the element contains any one of an MgO film and an Mg film.

10. The method of claim 1,
wherein the diffusing of the element in the film comprises diffusing the element in the film into the high-k insulating film.

11. The method of claim 1,
wherein the metal gate electrode includes any one of a titanium nitride film and a tantalum nitride film.

12. The method of claim 11,
wherein the metal gate electrode includes any one of a polysilicon film and a metal suicide film formed on any one of the titanium nitride film and the tantalum nitride film.

13. A semiconductor device comprising:
a first MISFET including:
a first gate insulating film including:
a first interfacial layer formed on a semiconductor substrate and having a first film thickness, wherein the first interfacial layer contains a first amount of at least one of elements of Mg, La, Y, Dy, Sc, Al per unit area; and
a first insulating film formed on the first interfacial layer and being made of a high-k material; and
a first metal gate electrode formed on the first gate insulating film; and
a second MISFET including:
a second gate insulating film including:
a second interfacial layer formed on the semiconductor substrate and having a second film thickness different from the first film thickness, wherein the second interfacial layer contains a second amount, different from the first amount, of the element per unit area; and
a second insulating film formed on the second interfacial layer and made of the high-k material; and
a second metal gate electrode formed on the second gate insulating film.

14. The device of claim 13,
wherein the second film thickness of the second interfacial layer is greater than the first film thickness of the first interfacial layer, and the second amount contained in the second interfacial layer is more than the first amount contained in the first interfacial layer.

15. The device of claim 13,
wherein the area of the second oxide film is larger than the area of the first oxide film.

16. The device of claim 13,
wherein the second MISFET has the almost same threshold voltage as the threshold voltage of the first MISFET.

17. The device of claim 13,
wherein the second insulating film has the same film thickness as the film thickness of the first insulating film.

18. The device of claim 13,
wherein the first and second insulating films include a hafnium oxide film.

19. The device of claim 13,
wherein the first and second metal gate electrodes include one of a titanium nitride film and a tantalum nitride film.

20. The device of claim 19,
wherein the first and second metal gate electrodes include one of a polysilicon film and a metal suicide film formed on the one of the titanium nitride film and the tantalum nitride film.
